(19) United States
(12) Patent Application Publication
(10) Pub. No.: US 2024/0349442 A1
(43) Pub. Date: Oct. 17, 2024

(54) MODULAR ENCLOSURE FOR AN IN-VEHICLE COMPUTER SYSTEM

(71) Applicant: TuSimple, Inc., San Diego, CA (US)

(72) Inventors: Stephen W. Horton, San Diego, CA (US); Shimeng Wang, San Diego, CA (US); Brian C. Zelle, Tucson, AZ (US); Holden James Yildirim, Tucson, AZ (US); Jami Frances Tullius, Tucson, AZ (US); Thomas Holladay Lind, Vail, AZ (US); Patrick James McNamara, Tucson, AZ (US); Sridhar Kumar, Fremont, CA (US)

(21) Appl. No.: 18/617,741

(22) Filed: Mar. 27, 2024

Related U.S. Application Data
(60) Provisional application No. 63/495,687, filed on Apr. 12, 2023.

(51) Int. Cl. H05K 7/14; H05K 7/20

(52) U.S. Cl. CPC H05K 7/1492; H05K 7/1495; H05K 7/20272; H05K 7/20872

(57) ABSTRACT

A modular enclosure is configured to house a set of components that facilitate the autonomous functions of an autonomous vehicle while meeting a set of requirements. The set of components comprises a sensor processing unit configured to detect objects from sensors associated with the autonomous vehicle, a compute unit configured to determine a navigation path for the autonomous vehicle, a vehicle control unit configured to control the autonomous function of the autonomous vehicle, a communication gateway configured to establish communication of the autonomous vehicle, and a data diagnostics unit configured to determine a health data for at least one component of the autonomous vehicle. The set of requirements comprises a space requirement, a communication requirement, a cooling requirement, and a shock absorption requirement.

This application claims priority to U.S. Provisional Patent Application Ser. No. 63/495,687 filed Apr. 12, 2023, and entitled “Modular Enclosure for an In-Vehicle Computer System,” which is incorporation herein by reference.

### TECHNICAL FIELD

The present disclosure relates generally to autonomous vehicles. More particularly, the present disclosure is related to a modular enclosure for an in-vehicle computer system.

### BACKGROUND

An in-vehicle computer system resides inside an autonomous vehicle and enables the autonomous vehicle to operate autonomously. The in-vehicle computer system includes many modules and components. The modules and components of the in-vehicle computer system are typically scattered in different chassis at different locations inside the autonomous vehicle.

### SUMMARY

This disclosure recognizes various problems and previously unmet needs related to autonomous vehicle technology, and more specifically to the lack of a modular enclosure that is able to house a set of components to facilitate the autonomous function of an autonomous vehicle while meeting a set of requirements, comprising a space requirement, a communication requirement, a cooling requirement, and a shock absorption requirement, the lack of enclosure that can be integrated into any semi-tractor truck and “plug-in” to the truck to connect to vehicle control components (e.g., breaks, steering wheel, engine, etc.) and sensors (e.g., cameras, Radars, etc.) and be able to facilitate the autonomous operations of the autonomous vehicle.

Certain embodiments of the present disclosure provide unique technical solutions to technical problems of current autonomous vehicle technology, including those problems described herein, to improve autonomous vehicle technology. More specifically, the present disclosure contemplates an unconventional enclosure that is configured to house a set of components (that are essential to facilitate the autonomous function of an autonomous vehicle) within a confined space while being able to meet the set of requirements. In particular, certain systems are designed and deployed with respect to the enclosure to allow the set of components to fit within the confined space as defined by the space requirements for the enclosure. The set of components includes a sensor processing unit, a compute unit, a vehicle control unit, a data diagnostics unit, and a communication gateway.

The disclosed system is configured to provide an enclosure that is modular-meaning that the enclosure is configured to be integrated into any semi-truck tractor unit, be connected to the sensors (and other components that control the movement of the vehicle), and enable the vehicle to operate autonomously. Therefore, the enclosure obviates the need for cables, chassis, and disparate components that make up the computing devices onboard an autonomous vehicle. For example, the modular enclosure may be installed in any vehicle without the need for additional cabling. This, in turn, reduces the installation time. Furthermore, in the long term, not having additional cabling will reduce the maintenance and tripping hazards. The modular enclosure provides connectors to be connected to the sensors and other components of the vehicle upon installation.

In the current practices, if the set of components is placed within a confined space, it would be challenging to provide appropriate power signal to each component so that each component is able to function with at least a minimum required power. Further, when the set of components is placed within a confined space, the components will be overheated as a result of electrical signals passing through layers and wires on circuit boards of the blades on which the components are placed. It would also be challenging to provide appropriate cooling to the components due to the components being closely spaced apart. If cables are used to distribute power to the components and enable the data communications of the components, the set of components will not fit within the required threshold space and/or satisfy the space requirements, communication requirements, or cooling requirements. The same applies to the blades on which the components are deployed. As the blades are placed closely together within a confined space, it becomes challenging to provide appropriate cooling, an appropriate power distribution, and communication lines to the blades.

The disclosed system provides a technical solution to these and other challenges in autonomous vehicle technology. For example, the disclosed system is configured to provide an appropriate power distribution among the components to allow communication throughput (e.g., data rate) more than a threshold communication throughput while being confined within a stringent physical space to satisfy the space requirement. For example, an unconventional backplane is designed and implemented for the enclosure, where the backplane includes transmission lines, circuit boards, bus wires, and the like configured to enable communicating power signals to the components, data communications among the components, and data communications from the enclosure to other devices, such as the vehicle subsystems, external devices, and the like.

The disclosed system is further configured to provide appropriate cooling to the components (implemented on the blades) by implementing a cooling system that is configured to satisfy the cooling requirement for the enclosure. The cooling requirement may indicate that the temperature within the enclosure is less than a threshold temperature (e.g., less than 18 degrees (° C.), less than 22 degrees (° C.), and the like). In one example, the cooling system may be coolant-based (e.g., liquid-based) and configured to pump the coolant through the pipes that circulate the coolant between the blades and a heat exchanger.

The disclosed system is further configured to provide shock absorption to the enclosure, for example, by implementing a shock absorption system to dampen the vibrations that may be generated from the movements of the autonomous vehicle while the autonomous vehicle is traveling on a road. Therefore, the safety and durability of the components are improved, e.g., by implementing the shock absorption system and the cooling system. Furthermore, the required communication throughput for the components is provided by the backplane, therefore, obviating the need for cabling that suffers from difficulty in maintenance and causes tripping hazards. In addition, cabling is more prone to electrical surges and damage at least because they are usually left on the floor.

In this manner, the components within the enclosure are kept secure from physical damage that may occur due to overheating and/or bumps on the road on which the autonomous vehicle is traveling. Furthermore, the modular enclosure provides technical improvements to the current autonomous vehicle technology by providing the ability to deploy and integrate the enclosure into any semi-tractor truck with minimum to no cabling, which reduces the deployment time and provides serviceability-meaning that the modular enclosure may be provided to autonomous vehicles as a “plug-in” solution to facilitate the autonomous navigation of the autonomous vehicles.

In certain embodiments, a system comprises an autonomous vehicle and an enclosure associated with the autonomous vehicle. The autonomous vehicle is configured to travel on a road autonomously. The enclosure is configured to house a set of components that facilitates the autonomous function of the autonomous vehicle. The set of components comprises a sensor processing unit, a compute unit, a vehicle control unit, a communication gateway, and a data diagnostics unit. The sensor processing unit is configured to detect objects from sensor data captured by at least one sensor. The compute unit is configured to determine a navigation path for the autonomous vehicle based at least in part upon an input signal received from the sensor processing unit. The vehicle control unit is configured to control the autonomous function of the autonomous vehicle based at least in part upon input signals received from other components from among the set of components. The communication gateway is configured to establish communications between the autonomous vehicle and other devices. The data diagnostics unit is configured to determine health data for at least one component of the autonomous vehicle. The enclosure is further configured to meet a set of requirements comprising a space requirement, a communication requirement, a cooling requirement, and a shock absorption requirement. The space requirement indicates that the enclosure is to have a dimension less than a threshold dimension. The communication requirement indicates to provide transmission lines to facilitate a communication throughput more than a threshold communication throughput among the set of components. The cooling requirement indicates to satisfy a threshold temperature within the enclosure. The shock absorption requirement indicates to satisfy a threshold damping factor. The enclosure comprises a backplane that is configured to satisfy the communication requirement. The backplane comprises the transmission lines that enable communications among the components of the set of components. The backplane is connected to a set of manifolds configured to circulate a coolant between a heat exchanger and the set of components. The backplane further comprises a set of connectors to connect at least one of the set of components to the at least one sensor. The backplane is positioned across a side of the set of components and against a back wall of the enclosure.

Certain embodiments of this disclosure may include some, all, or none of these advantages. These advantages and other features will be more clearly understood from the following detailed description taken in conjunction with the accompanying drawings and claims.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 illustrates an embodiment of a system configured to provide a modular enclosure that is configured to house a set of components to facilitate the autonomous function of an autonomous vehicle while meeting a set of requirements;

FIGS. 2A and 2B illustrate isometric views of an embodiment of a modular enclosure of FIG. 1;

FIG. 3 illustrates a block diagram of an example autonomous vehicle configured to implement autonomous driving operations;

FIG. 4 illustrates an example system for providing autonomous driving operations used by the autonomous vehicle of FIG. 3;

FIG. 5 illustrates a block diagram of an in-vehicle control computer included in the autonomous vehicle of FIG. 3;

FIG. 6 illustrates an example configuration for a stack of layers in circuit boards used in connecting one component of the enclosure of FIG. 1;

FIG. 7 illustrates an embodiment of a via for use in a circuit board that connects one component of the enclosure of FIG. 1 from one layer to another component of the enclosure in another layer of a circuit board;

FIG. 8 illustrates an example schematic diagram of a circuit for modeling a communication path between two components or between two blades;

FIG. 9 illustrates an example schematic diagram of a circuit for modeling a communication path from a first component to a second component to a third component of the enclosure of FIG. 1; and

FIG. 10 illustrates an isometric view of an example embodiment of a blade used in the enclosure of FIG. 1.

### DETAILED DESCRIPTION

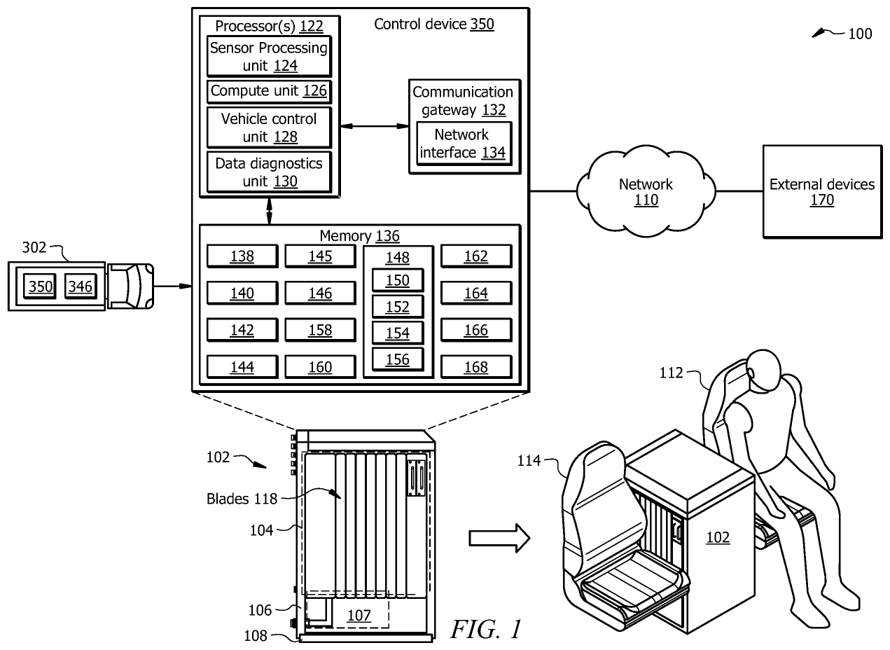

As described above, previous technologies fail to provide efficient, reliable, and safe solutions to house a set of components that facilitate the autonomous function of an autonomous vehicle while meeting a set of requirements. The present disclosure provides various systems, methods, and devices to provide a modular enclosure configured to house a set of components that facilitate the autonomous function of an autonomous vehicle while meeting a set of requirements. Embodiments of the present disclosure and its advantages may be understood by referring to FIGS. 1 through 10. FIGS. 1 through 10 are used to describe a system and method to provide a modular enclosure configured to house a set of components that facilitate the autonomous function of an autonomous vehicle while meeting a set of requirements.

### System Overview

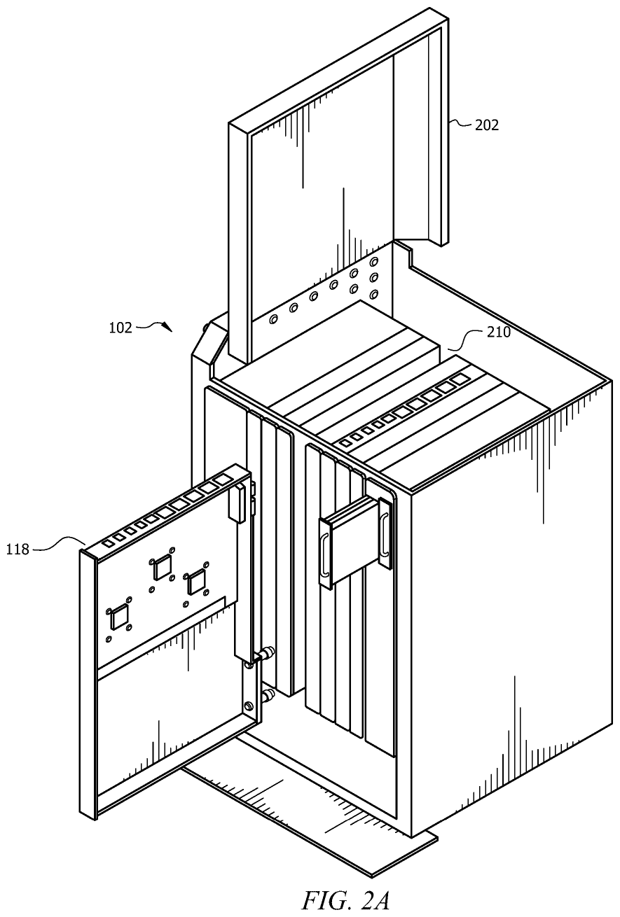

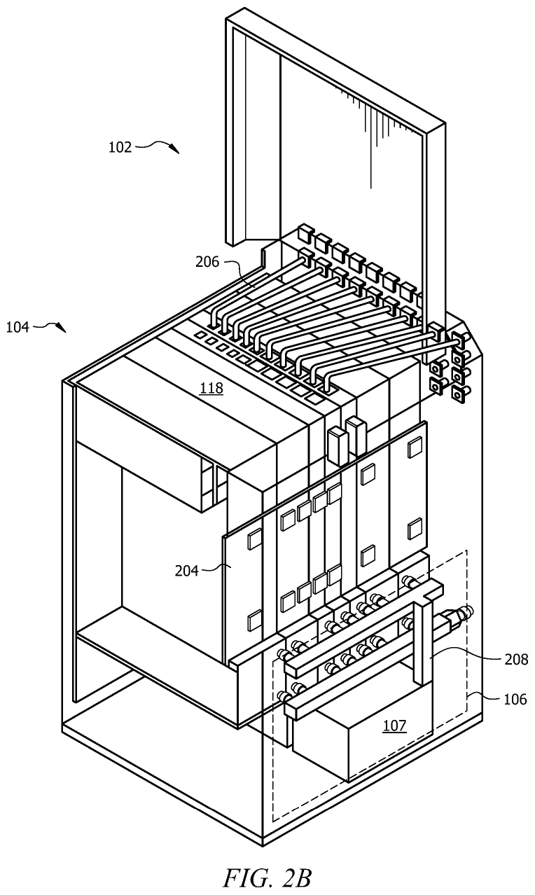

FIG. 1 illustrates an embodiment of a system 100 configured to provide a modular enclosure 102 that is configured to house a set of components 104 that may facilitate the autonomous function of an autonomous vehicle 302 while meeting a set of requirements 148, comprising a space requirement 150, a communication requirement 152, a cooling requirement 154, and a shock absorption requirement 156. The modular enclosure 102 is interchangeably referred to herein as an enclosure. In certain embodiments, the system 100 comprises an autonomous vehicle 302 and one or more external devices 170 communicatively coupled to the autonomous vehicle 302 and its components via a network 110. Network 110 enables communications among the components of the system 100. For example, the network 110 allows the autonomous vehicle 302 to communicate with external devices 170 and vice versa. Example embodiments of the enclosure 102 are described in the discussion of FIGS. 1, 2A, and 2B. The autonomous vehicle 302 comprises a control device 350. The control device 350 is housed within the enclosure 102. The control device 350 generally facilitates the autonomous operations of the autonomous vehicle 302. The control device 350 comprises one or more processors 122 in signal communication with a memory 136. Memory 136 stores software instructions 138 that when executed by the processor(s) 122 cause the control device 350 to perform one or more operations described herein. Examples of the external devices 170 may include an oversight server, other autonomous vehicles, and the like. The oversight server may be configured to provide software resources (e.g., software updates, navigation commands, and/or any other data) to the autonomous vehicles 302. In other embodiments, system 100 may not have all of the components listed and/or may have other elements instead of, or in addition to, those listed above. System 100 may be configured as shown or in any other configuration.

In general, the system 100 provides several practical applications, technical improvements, and technical advantages that overcome the previously unmet technical problems in autonomous vehicle technology-which are described below. The system 100 is configured to reduce the form-factor of the set of components 104. In particular, certain systems are designed and deployed with respect to the enclosure 102 to allow the essential set of components 104 to fit within the confined space as defined by the space requirements 150 for the enclosure 102. The system 100 is further configured to provide the enclosure 102 that is modular-meaning that the enclosure 102 is configured to be integrated into any semi-truck tractor unit, be connected to the sensors 346 (and other components that control the movement of the vehicle), and enable the vehicle to operate autonomously. Therefore, the enclosure 102 obviates the need for cables, chassis, and scattered disparate components that make up the computing devices onboard an autonomous vehicle 302. For example, the modular enclosure 102 may be installed in any vehicle without the need for additional cabling that may include sensor cables and truck harness. The modular enclosure 102 provides connectors to be connected to the sensors 346 and other components of the vehicle upon installation.

In the current practices, if the set of components 104 is placed within a confined space, it would be challenging to provide appropriate power signals to each component 104 so that each component 104 is able to function with at least a minimum required power. Further, when the set of components 104 is placed within a confined space, the components 104 will be overheated as a result of electrical signals passing through layers, components, and wires on circuit boards of the blades on which the components 104 are placed. It would also be challenging to provide appropriate cooling to the components 104 due to the components being closely spaced apart. If cables are used to distribute power signals to the components 104 and enable the data communications of the components 104, the set of components 104 would not fit within the required threshold space or satisfy the space requirements 150 in the current practices. The same applies to the blades 118 on which the components 104 are deployed. As the blades 118 are placed closely together within a confined space, it becomes challenging to provide appropriate cooling and an appropriate power distribution to the blades 118.

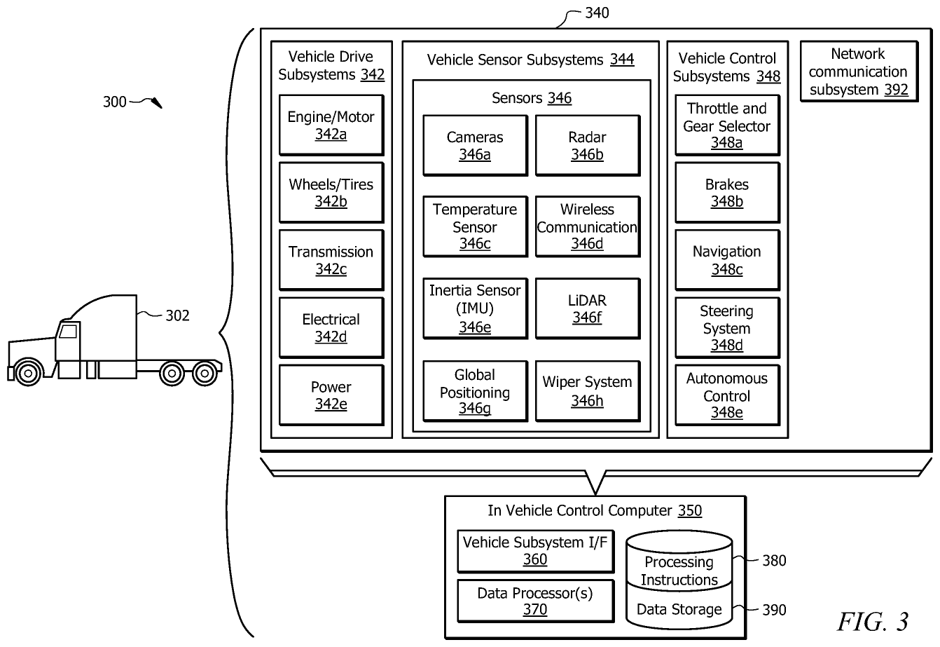

The system 100 provides a solution to these and other challenges in autonomous vehicle technology. For example, the system 100 is configured to provide an appropriate power distribution and sequencing among the components 104 to allow communication throughput (e.g., data rate) more than a threshold communication throughput 160. For example, an unconventional backplane 204 (see FIG. 2B) is designed and implemented for the enclosure 102, where the backplane includes transmission lines, circuit boards, bus wires, and the like, configured to enable communication power signals to the components 104, data communications among the components 104, and data communications from the enclosure 102 to other devices, such as the vehicle subsystems (340 in FIG. 3), external devices 170, and the like. The backplane is described in more details in the discussion of the FIG. 2B.

The system 100 is further configured to provide appropriate cooling to the components 104 (and blades 118) by implementing a cooling system 106 that is configured to satisfy the cooling requirement 154 for the enclosure 102. The cooling requirement 154 may indicate that the temperature within the enclosure 102 is less than a threshold temperature 162 (e.g., less than 18 degrees (° C.), less than 22 degrees (° C.), and the like). In one example, the cooling system 106 may be liquid-based and configured to pump cooled liquid through the pipes that circulate through the blades 118.

The system 100 is further configured to provide shock absorption to the enclosure 102, for example, by implementing a shock absorption system 108 to dampen the vibrations that may be generated from movements of the autonomous vehicle 302 while the autonomous vehicle 302 is traveling on a road. Therefore, the safety and durability of the components 104 are improved, e.g., by implementing the shock absorption system 108 and the cooling system 106. Furthermore, the required communication throughput for the components 104 is provided by the backplane (204 in FIG. 2A), therefore, obviating the need for additional cabling that suffers from difficulty in maintenance and causes tripping hazards. In addition, typical cabling is prone to electrical surges and damage at least because they are usually left on the floor or other unprotected areas.

In this manner, the components 104 are kept secure from physical damage that may occur due to overheating and/or bumps on the road on which the autonomous vehicle 302 is traveling. Furthermore, the modular enclosure 102 provides technical improvements to the current autonomous vehicle technology by providing the ability to deploy and integrate the enclosure 102 into any semi-tractor truck with minimum to no cabling, which reduces the deployment time. Furthermore, the modular enclosure 102 provides an additional technical improvement to the current autonomous vehicle by providing serviceability-meaning that the modular enclosure 102 may be provided to autonomous vehicles as a “plug-in” product to facilitate the autonomous navigation of the autonomous vehicles.

### System Components

Network 110 may include any interconnecting system capable of transmitting audio, video, signals, data, messages, or any combination of the preceding. Network 110 may include all or a portion of a local area network (LAN), a wide area network (WAN), a metropolitan area network (MAN), a personal area network (PAN), a wireless PAN (WPAN), an overlay network, a software-defined network (SDN), a virtual private network (VPN), a packet data network (e.g., the Internet), a mobile telephone network (e.g., cellular networks, such as 4G or 5G), a plain old telephone (POT) network, a wireless data network (e.g., WiFi, WiGig, WiMAX, etc.), a long-term evolution (LTE) network, a universal mobile telecommunications system (UMTS) network, a peer-to-peer (P2P) network, a Bluetooth network, a near field communication (NFC) network, a Zigbee network, a Z-wave network, a WiFi network, and/or any other suitable network.

### Example Autonomous Vehicle

In certain embodiments, the autonomous vehicle 302 may include a semi-truck tractor unit attached to a trailer to transport cargo or freight from one location to another location (see FIG. 3). The autonomous vehicle 302 is generally configured to travel along a road in an autonomous mode. The autonomous vehicle 302 may navigate using a plurality of components described in detail in FIGS. 3-5. The operation of the autonomous vehicle 302 is described in greater detail in FIGS. 3-5. The corresponding description below includes brief descriptions of certain components of the autonomous vehicle 302.

Control device 350 may be generally configured to control the operation of the autonomous vehicle 302 and its components and to facilitate autonomous driving of the autonomous vehicle 302. The control device 350 may be further configured to determine a pathway in front of the autonomous vehicle 302 that is safe to travel and free of objects or obstacles, and navigate the autonomous vehicle 302 to travel in that pathway. This process is described in more detail in FIGS. 3-5. The control device 350 may generally include one or more computing devices in signal communication with other components of the autonomous vehicle 302 (see FIG. 3). In this disclosure, the control device 350 may interchangeably be referred to as an in-vehicle control computer 350.

The control device 350 may be configured to detect objects on and around a road traveled by the autonomous vehicle 302 by analyzing the sensor data 140 and/or map data 142. For example, the control device 350 may detect objects on and around the road by implementing object detection machine learning modules 146. The object detection machine learning modules 146 may be implemented using neural networks and/or machine learning algorithms for detecting objects from images, videos, infrared images, point clouds, audio feed, Radar data, etc. The object detection machine learning modules 146 are described in more detail further below. The control device 350 may receive sensor data 140 from the sensors 346 positioned on the autonomous vehicle 302 to determine a safe pathway to travel. The sensor data 140 may include data captured by the sensors 346.

Sensors 346 may be configured to capture any object within their detection zones or fields of view, such as landmarks, lane markers, lane boundaries, road boundaries, vehicles, pedestrians, road/traffic signs, among others. In some embodiments, the sensors 346 may be configured to detect rain, fog, snow, and/or any other weather condition. The sensors 346 may include a detection and ranging (LiDAR) sensor, a Radar sensor, a video camera, an infrared camera, an ultrasonic sensor system, a wind gust detection system, a microphone array, a thermocouple, a humidity sensor, a barometer, an inertial measurement unit, a positioning system, an infrared sensor, a motion sensor, a rain sensor, and the like. In some embodiments, the sensors 346 may be positioned around the autonomous vehicle 302 to capture the environment surrounding the autonomous vehicle 302. See the corresponding description of FIG. 3 for further description of the sensors 346.

### Control Device

The control device 350 is described in greater detail in FIG. 3. In brief, the control device 350 may include the processor(s) 122 in signal communication with the memory 136 and a communication gateway 132. The processor(s) 122 may include one or more processing units that perform various functions described herein. The memory 136 may store any data and/or instructions used by the processor(s) 122 to perform its functions. For example, the memory 136 may store software instructions 138 that when executed by the processor(s) 122 causes the control device 350 to perform one or more functions described herein.

The processor 122 may be one of the data processors 370 described in FIG. 3. The processor 122 comprises one or more processors. The processor 122 may be any electronic circuitry, including state machines, one or more central processing unit (CPU) chips, logic units, cores (e.g., a multi-core processor), field-programmable gate arrays (FPGAs), application-specific integrated circuits (ASICs), or digital signal processors (DSPs). The processor 122 may be a programmable logic device, a microcontroller, a microprocessor, or any suitable combination of the preceding. The processor 122 may be communicatively coupled to and in signal communication with the communication gateway 132 that includes the network interface 134 and memory 136. The one or more processors may be configured to process data and may be implemented in hardware or software. For example, the processor 122 may be 8-bit, 16-bit, 32-bit, 64-bit, or of any other suitable architecture. The processor 122 may include an arithmetic logic unit (ALU) for performing arithmetic and logic operations, processor registers that supply operands to the ALU and store the results of ALU operations, and a control unit that fetches instructions from memory and executes them by directing the coordinated operations of the ALU, registers and other components. The one or more processors may be configured to implement various instructions. For example, the one or more processors may be configured to execute software instructions 138 to implement the functions disclosed herein, such as some or all of those described with respect to FIGS. 1-5. In some embodiments, the function described herein is implemented using logic units, FPGAs, ASICS, DSPs, or any other suitable hardware or electronic circuitry.

The processor(s) 122 may include a sensor processing unit 124, a compute unit 126, a vehicle control unit 128, and a data diagnostics unit 130. The processor(s) 122 are operably coupled to one another and to other components of the control device 350.

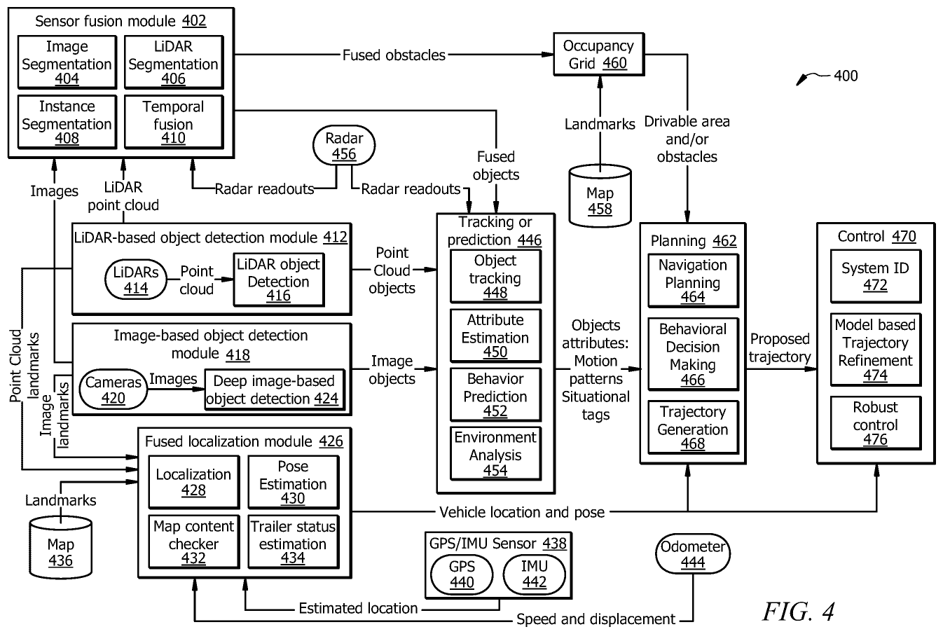

The sensor processing unit 124 may include one or more hardware and/or software processors that are configured to process the sensor data 140 and detect objects from the sensor data 140 captured by the sensors 346. In certain embodiments, the sensor processing unit 124 may perform pre-processing on the sensor data 140 before communicating it to another unit. The pre-processing may include initial identification of objects detected from the sensor data 140, among other operations. In certain embodiments, the sensor processing unit 124 may communicate data with any of the vehicle subsystems (340 in FIG. 3) and perform one or more operations described in FIG. 4.

The compute unit 126 may include one or more hardware and/or software processors that are configured to determine a navigation path for the autonomous vehicle 302 based at least on the input signals received from the sensor processing unit 124. In certain embodiments, the compute unit 126 may communicate data with any of the vehicle subsystems (340 in FIG. 3) and perform one or more operations described in FIG. 4.

The vehicle control unit 128 may include one or more hardware and/or software processors that are configured to control the autonomous function of the autonomous vehicle 302 based at least on the input signals received from other components of the control device 350, including the components 104. The vehicle control unit 128 may also be referred to as a vehicle control and interface unit. In certain embodiments, the vehicle control unit 128 may communicate data with any of the vehicle subsystems (340 in FIG. 3) and perform one or more operations described in FIG. 4.

The data diagnostics unit 130 may include one or more hardware and/or software processors that are configured to determine a health data for each component of the autonomous vehicle 302. The health data may indicate, for example, performance percentage, capacity, utilization, fuel level, oil level, tire air level, operating temperature, and any other indications that may convey a health of a component.

Communication gateway 132 may include the network interface 134. The Network interface 134 may be a component of the network communication subsystem 392 described in FIG. 3. The network interface 134 may be configured to enable wired and/or wireless communications. The network interface 134 may be configured to communicate data between the autonomous vehicle 302 and other devices, systems, or domains (correctively referred to herein as external devices 170). For example, the network interface 134 may comprise an NFC interface, a Bluetooth interface, a Zigbee interface, a Z-wave interface, a radio-frequency identification (RFID) interface, a WIFI interface, a local area network (LAN) interface, a wide area network (WAN) interface, a metropolitan area network (MAN) interface, a personal area network (PAN) interface, a wireless PAN (WPAN) interface, a modem, a switch, and/or a router. The processor 122 may be configured to send and receive data using the network interface 134. The network interface 134 may be configured to use any suitable type of communication protocol as would be appreciated by one of ordinary skill in the art.

The memory 136 may be one of the data storages 390 described in FIG. 3. The memory 136 may be volatile or non-volatile and may comprise read-only memory (ROM), random-access memory (RAM), ternary content-addressable memory (TCAM), dynamic random-access memory (DRAM), and static random-access memory (SRAM). The memory 136 may include one or more of a local database, cloud database, network-attached storage (NAS), etc. The memory 136 may store any of the information described in FIGS. 1-5 along with any other data, instructions, logic, rules, or code operable to implement the function(s) described herein when executed by processor 122. For example, the memory 136 may store software instructions 138, sensor data 140, map data 142, driving instructions 144, routing plan 145, object detection machine learning modules 146, requirements 148, threshold dimension 158, threshold communication throughput 160, threshold temperature 162, threshold damping factor 164, and/or any other data/instructions. The software instructions 138 include code that when executed by the processor(s) 122 causes the control device 350 to perform the functions described herein, such as some or all of those described in FIGS. 1-5. The memory 136 comprises one or more disks, tape drives, or solid-state drives, and may be used as an over-flow data storage device to store programs when such programs are selected for execution, and to store instructions and data that are read during program execution.

Map data 142 may include a virtual map of a city or an area that includes the road traveled by an autonomous vehicle 302. In some examples, the map data 142 may include the map 458 and map database 436 (see FIG. 4 for descriptions of the map 458 and map database 436). The map data 142 may include drivable areas, such as roads, paths, highways, and undrivable areas, such as terrain (determined by the occupancy grid module 460, see FIG. 4 for descriptions of the occupancy grid module 460). The map data 142 may specify location coordinates of road signs, lanes, lane markings, lane boundaries, road boundaries, traffic lights, obstacles, etc.

Driving instructions 144 may be implemented by the planning module 462 (Sec descriptions of the planning module 462 in FIG. 4). The driving instructions 144 may include instructions and rules to adapt the autonomous driving of the autonomous vehicle 302 according to the driving rules of each stage of the routing plan 145. For example, the driving instructions 144 may include instructions to stay within the speed range of a road traveled by the autonomous vehicle 302, adapt the speed of the autonomous vehicle 302 with respect to observed changes by the sensors 346, such as speeds of surrounding vehicles, objects within the detection zones of the sensors 346, etc.

Routing plan 145 may be a plan for traveling from a start location (e.g., a first autonomous vehicle launchpad/landing pad) to a destination (e.g., a second autonomous vehicle launchpad/landing pad). For example, the routing plan 145 may specify a combination of one or more streets, roads, and highways in a specific order from the start location to the destination. The routing plan 145 may specify stages, including the first stage (e.g., moving out from a start location/launch pad), a plurality of intermediate stages (e.g., traveling along particular lanes of one or more particular street/road/highway), and the last stage (e.g., entering the destination/landing pad). The routing plan 145 may include other information about the route from the start position to the destination, such as road/traffic signs in that routing plan 145, etc.

Object detection machine learning modules 146 may be implemented by the processor 122 executing software instructions 138, and may be generally configured to detect objects and obstacles from the sensor data 140. The object detection machine learning modules 146 may be implemented using neural networks and/or machine learning algorithms for detecting objects from any data type, such as images, videos, infrared images, point clouds, audio feed, Radar data, etc.

In some embodiments, the object detection machine learning modules 146 may be implemented using machine learning algorithms, such as Support Vector Machine (SVM), Naive Bayes, Logistic Regression, k-Nearest Neighbors, Decision Trees, or the like. In some embodiments, the object detection machine learning modules 146 may utilize a plurality of neural network layers, convolutional neural network layers, Long-Short-Term-Memory (LSTM) layers, Bi-directional LSTM layers, recurrent neural network layers, and/or the like, in which weights and biases of these layers are optimized in the training process of the object detection machine learning modules 146. The object detection machine learning modules 146 may be trained by a training dataset that may include samples of data types labeled with one or more objects in each sample. For example, the training dataset may include sample images of objects (e.g., vehicles, lane markings, pedestrians, road signs, obstacles, etc.) labeled with object(s) in each sample image. Similarly, the training dataset may include samples of other data types, such as videos, infrared images, point clouds, audio feed, Radar data, etc., labeled with object(s) in each sample data. The object detection machine learning modules 146 may be trained, tested, and refined by the training dataset and the sensor data 140. The object detection machine learning modules 146 use the sensor data 140 (which are not labeled with objects) to increase their accuracy of predictions in detecting objects. Similar operations and embodiments may apply for training the object detection machine learning modules 146 using the training dataset that includes sound data samples each labeled with a respective sound source and a type of sound. For example, supervised and/or unsupervised machine learning algorithms may be used to validate the predictions of the object detection machine learning modules 146 in detecting objects in the sensor data 140.

### Modular Enclosure

The modular enclosure 102 may be a physical structural component that is configured to house the set of components 104. The enclosure 102 is further configured to meet a set of requirements 148. The set of requirements 148 may include a space requirement 150, a communication requirement 152, a cooling requirement 154, and a shock absorption requirement 156.

The space requirement 150 may indicate that the enclosure 102 to have a dimension less than a threshold dimension 158. In other words, the space requirement 150 may indicate that the enclosure 102 should occupy less than the threshold dimension 158 in the physical space. In one example, the threshold dimension 158 may be 36 inches×24 inches×22 inches. In the same or other examples, the threshold dimension 158 may be any suitable dimension that can fit between the driver seat 112 and the passenger seat 114 in a semi-tractor truck and has a height less than a shoulder-level height of a driver (while sitting in the driver seat 112) to allow the driver to view outside the vehicle from side and back windows. In certain embodiments, the enclosure 102 is configured to fit within a threshold volume of space. For example, the enclosure 102 may be configured to fit between a driver seat 112 and a passenger seat 114 in a cabin of the autonomous vehicle 302.

The communication requirement 152 may indicate to provide at least a threshold communication throughput 160 among the components 104, between the components 104 and the external devices 170, and between the components 104 and other components of the autonomous vehicle 302. For example, the communication requirement 152 may be met by transmission lines, cables, and bus wires capable of transmitting data with at least the threshold communication throughput 160. The communication throughput 160 may be referred to as data bitrate. In certain embodiments, the communication requirement 152 may also indicate to supply power (and voltage) signals to the components 104 to maintain the circuit boards of the components 104 operational. In certain embodiments, the communication requirement 152 may also indicate to maintain signal integrity more than a threshold signal integrity, such as a threshold jitter noise, a threshold data package loss, a threshold signal bandwidth, and the like for the data communications of the components 104.

The cooling requirement 154 may indicate to satisfy a threshold temperature 162 within the enclosure 102. The threshold temperature 162 maybe 18 degrees (° C.), 22 degrees (° C.), and the like. The shock absorption requirement 156 may indicate to satisfy a threshold damping factor 164. For example, as the autonomous vehicle 302 travels on a road, the enclosure 102 may experience vibrations from the movements of the autonomous vehicle 302. The shock absorption requirement 156 may be used to determine if the vibrations are dampened below the threshold damping factor 164.

### Blades

The components 104 may be implemented on blades 118. Each blade 118 may be a thin server or other electronic component that is configured to fit into a bay within the enclosure 102. Each blade 118 may include a computing system that is configured to perform the operations of one or more component 104. In the illustrated embodiment, the blades 118 are vertically positioned inside the enclosure 102. In other embodiments, the blades 118 may be positioned horizontally and/or in any orientation. In the illustrated embodiment, the blades 118 are positioned above the pump 107. In other embodiments, the blades 118 may be positioned at any location with respect to the pump 107. In certain embodiments, each component 104 may be implemented in a single blade 118. Thus, if a component 104 ever needs to be updated, changed, or serviced, the currently in place blade 118 (that hosts the component 104) may be replaced with a new blade 118. In certain embodiments, a component 104 may be implemented in multiple blades 118. In certain embodiments, multiple components 104 may be implemented on a single blade 118. Each blade 118 may include a set of connectors configured to accept one or more manifolds of the cooling systems 106. For example, the set of connectors on the blade 118 may be connected to the manifolds of the cooling system 106 to allow the circulation of the cooled liquid through the pipes of the cooling system 106 through the blades 118 and cooling down the blades 118.

Each blade 118 may also include a set of connectors that are configured to accept transmission lines, bus wires, and the like that from one side are connected to the backplane (204 in FIG. 2B) and associated with the backplane. Each blade 118 may be configured to be connected to the one or more manifolds of the cooling systems 106 and the transmission lines, bus wires, etc. when the blade 118 is slid into a bay within the enclosure 102.

### Cooling System

In certain embodiments, the enclosure 102 may include a cooling system 106 that is configured to satisfy the cooling requirement 154. The cooling system 106 may include a set of manifolds that is configured to pump and flow a cooled liquid toward the set of components 104 (implemented on the blades 118). For example, the set of manifolds may be connected to a set of pipes in which the liquid flows. The set of pipes may run through the components 104 (implemented on the blades 118). When the cooled liquid flows through the pipes from the inlets, it reduces the temperature of the electrical components on the blades 118. The cooled liquid is circulated through the blades 118. After the circulation, the liquid absorbs the heat from the electrical components on the blades 118 and this warms up the liquid inside the pipes. The warmed-up liquid flows out from the outlets to one or more heat exchangers (e.g., chillers or radiators. The heat exchangers cool down the liquid so that it can be circulated back into the blades 118. The cooling system 106 further includes a pump 107 (e.g., a single pump, a dual pump, etc.) configured to pump the cooled liquid to the components 104 (or the blades 118).

In certain embodiments, the control device 350 may monitor the temperature within the enclosure 102 by temperature sensor(s) placed within the enclosure 102. The control device 350 may communicate fluid control commands 166 to the cooling system 106 to control the flow of the coolant (e.g., liquid) through the pipes. For example, if the temperature detected by the temperature sensor(s) reaches above the threshold temperature 162, the control device 350 may communicate a fluid control command 166 that leads to flowing a lower-temperature liquid through the pipes that run through the blades 118. In another example, the fluid control command 166 may indicate to increase the flow rate (or circulation rate) of the cooled liquid until the temperature detected by the temperature sensor(s) is at least the threshold temperature 162.

### Shock Absorption System

In certain embodiments, the enclosure 102 may include a shock absorption system 108 that is configured to satisfy the shock absorption requirement 156. In certain embodiments, the shock absorption system 108 may be implemented underneath the enclosure 102. In other embodiments, the shock absorption system 108 may be implemented in any suitable location. In certain embodiments, the shock absorption system 108 may be separate from and in addition to the shock absorption system that is underneath the cabin of the autonomous vehicle 302 and above the tires.

The shock absorption system 108 may include multiple shock absorbers or dampeners positioned at different locations. For example, the shock dampeners or absorbers may be placed underneath the enclosure 102, below the blades 118, below the pump 107, between the blades 118 and the pump 107, or in any other suitable locations. Each shock absorber may be configured to absorb or dampen the vibrations caused by movements of the autonomous vehicle 302 while traveling and movements caused by a person roaming inside the cabin of the autonomous vehicle 302. In other words, shock absorber may be configured to absorb or dampen compression and rebound of the springs and suspension. In certain embodiments, the shock absorbers may be formed from absorbing polymers, viscoelastic polymers, visco polymers, rubber, neoprene, silicone, etc.

In certain embodiments, the shock absorption system 108 may provide vibration data 168 to the control device 350. The vibration data 168 may indicate a damping factor and levels of movement (e.g., vertical movement) of the enclosure 102, the blades 118, and/or other components within the enclosure 102 with respect to the road. The control device 350 may analyze the vibration data 168 and determine if the shock absorption requirement 156 is met, e.g., if the damping factor indicated by the vibration data 168 is less than the threshold damping factor and/or the enclosure 102 reaches a steady state within a threshold time period (e.g., within five seconds, ten seconds, etc.). If the control device 350 determines that the enclosure 102 determines that the shock absorption requirement 156 is not met and/or the enclosure 102 does not reach the steady state within the threshold period, the control device 350 may update the routing plan 145 to avoid further bumps on the road. The control device 350 may flag the shock absorption system 108 to be serviced upon arrival at a destination.

### Example Functions of the Enclosure

FIG. 2A illustrates an isometric view of an embodiment of the enclosure 102. As can be seen in FIG. 2A, the enclosure 102 has an upper lid 202 that may be opened or lifted from one end to allow access to the interior of the enclosure 102 and ultimately the blades 118. In certain embodiments, the lid 202 may be used to lock the blades 118 to prevent them from being removed. In certain embodiments, the lid 202 may be configures to actuate a locking bar mechanism that is configured to lock the enclosure 102 from opening when the lid 202 is closed. The locking bar mechanism may prevent the blades 118 from being removed from the enclosure 102 when the lid 202 is closed. By including a lock on the lid 202, it provides a security feature to minimize the ability for unauthorized tampering. By only allowing the blades 118 to be removed when the lid 202 is open also helps visually remind users that internal cables must be disconnected prior to the removal of certain blades 118, helping minimize potential inadvertent damage to the blades 118, the cables, and/or other components of the enclosure 102.

Each blade 118 may be slid in or inserted into a bay 210 (e.g., a designated location) within the enclosure 102. In the illustrated embodiment, the interior of enclosure 102 may also be accessed from a side to allow insertion of the blade 118 into a respective bay 210.

FIG. 2B illustrates an isometric view of an embodiment of the enclosure 102 where a side plane is shown transparent to show the interior of the enclosure 102. In the example of FIG. 2B, certain components of the cooling system 106, the backplane 204, and sensor harnessing 206 are shown. As mentioned in FIG. 1, the cooling system 106 includes a set of pipes 208 to allow the flow of the cooled liquid through the blades 118. For example, the set of pipes 208 may have connectors that accept counterpart connectors on the backplane 204. When a blade 118 is inserted into a bay, the blade 118 may be plugged-in into the cooling system 106 via the connectors on the backplane 204 and the pipes 208. The manifolds of the cooling system 106 are connected to the pump 107 on the inlet side and connected to the blades 118 on the outlet side. After the liquid is circulated through the blades 118, the blades 118 are cooled down, the liquid warms up, and circulates into a heat exchanger (e.g., a chiller or radiator) to be cooled down again.

The enclosure 102 may include the backplane 204 that is configured to satisfy the communication requirement (152 in FIG. 1). The backplane 204 may include connection wires, bus lines, transmission lines, and the like, to facilitate the communications within the components (104 in FIG. 1) and from the components (104 in FIG. 1) to devices outside the enclosure 102. The backplane 204 may be designed to include circuit boards to perform the operations of the components (104 in FIG. 1). The backplane 204 may reduce cabling and assembling time. The backplane 204 may also be one of the aspects leading to the enclosure 102 being serviceable and modular-meaning that the enclosure 102 may be integrated into any autonomous vehicle 302 to facilitate its autonomous functions. The backplane 204 may be connected to a set of manifolds of the cooling system 106, where the set of manifolds is configured to flow a cooled liquid toward the components (104 in FIG. 1) or the blades 118.

The backplane 204 may further include a set of connectors to connect at least one of the components (e.g., the sensor processing unit 124 in FIG. 1) to the sensors of the autonomous vehicle. In the illustrated embodiment, the backplane 204 is positioned across a side of (e.g., longitudinally at one side of) the set of components (104 in FIG. 1) or the blades 118 and against a back wall of the enclosure 102. In other embodiments, the backplane 204 may be positioned at any suitable location with respect to the components (104 in FIG. 1) or the blades 118. In some embodiments, the sensor harnessing 206 may include wires that provide the connection between the blades 118 and the sensors (346 in FIG. 3). Optionally or in addition, the sensor harnessing 206 may include wires that provide the connection between the blade 118 and a bulkhead. For example, some wires may connect the blades 118 to the sensors via the bulkhead.

### Example Autonomous Vehicle and its Operation

FIG. 3 shows a block diagram of an example vehicle ecosystem 300 in which autonomous driving operations can be determined. As shown in FIG. 3, the autonomous vehicle 302 may be a semi-trailer truck. The vehicle ecosystem 300 may include several systems and components that can generate and/or deliver one or more sources of information/data and related services to the in-vehicle control computer 350 that may be located in an autonomous vehicle 302. The in-vehicle control computer 350 can be in data communication with a plurality of vehicle subsystems 340, all of which can be resident in the autonomous vehicle 302. A vehicle subsystem interface 360 may be provided to facilitate data communication between the in-vehicle control computer 350 and the plurality of vehicle subsystems 340. In some embodiments, the vehicle subsystem interface 360 can include a controller area network (CAN) controller to communicate with devices in the vehicle subsystems 340.

The autonomous vehicle 302 may include various vehicle subsystems that support the operation of the autonomous vehicle 302. The vehicle subsystems 340 may include a vehicle drive subsystem 342, a vehicle sensor subsystem 344, a vehicle control subsystem 348, and/or network communication subsystem 392. The components or devices of the vehicle drive subsystem 342, the vehicle sensor subsystem 344, and the vehicle control subsystem 348 shown in FIG. 3 are examples. The autonomous vehicle 302 may be configured as shown or any other configurations.

The vehicle drive subsystem 342 may include components operable to provide powered motion for the autonomous vehicle 302. In an example embodiment, the vehicle drive subsystem 342 may include an engine/motor 342a, wheels/tires 342b, a transmission 342c, an electrical subsystem 342d, and a power source 342c.

The vehicle sensor subsystem 344 may include a number of sensors 346 configured to sense information about an environment or condition of the autonomous vehicle 302. The vehicle sensor subsystem 344 may include one or more cameras 346a or image capture devices, a radar unit 346b, one or more thermal sensors 346c, a wireless communication unit 346d (e.g., a cellular communication transceiver), an inertial measurement unit (IMU) 346e, a laser range finder/LiDAR unit 346f, a Global Positioning System (GPS) transceiver 346g, a wiper control system 346h. The vehicle sensor subsystem 344 may also include sensors configured to monitor internal systems of the autonomous vehicle 302 (e.g., an 02 monitor, a fuel gauge, an engine oil temperature, etc.).

The IMU 346e may include any combination of sensors (e.g., accelerometers and gyroscopes) configured to sense position and orientation changes of the autonomous vehicle 302 based on inertial acceleration. The GPS transceiver 346g may be any sensor configured to estimate a geographic location of the autonomous vehicle 302. For this purpose, the GPS transceiver 346g may include a receiver/transmitter operable to provide information regarding the position of the autonomous vehicle 302 with respect to the Earth. The radar unit 346b may represent a system that utilizes radio signals to sense objects within the local environment of the autonomous vehicle 302. In some embodiments, in addition to sensing the objects, the radar unit 346b may additionally be configured to sense the speed and the heading of the objects proximate to the autonomous vehicle 302. The laser range finder or LiDAR unit 346f may be any sensor configured to use lasers to sense objects in the environment in which the autonomous vehicle 302 is located. The cameras 346a may include one or more devices configured to capture a plurality of images of the environment of the autonomous vehicle 302. The cameras 346a may be still image cameras or motion video cameras.

Cameras 346a may be rear-facing and front-facing so that pedestrians, and any hand signals made by them or signs held by pedestrians, may be observed from all around the autonomous vehicle. These cameras 346a may include video cameras, cameras with filters for specific wavelengths, as well as any other cameras suitable to detect hand signals, hand-held traffic signs, or both hand signals and hand-held traffic signs. A sound detection array, such as a microphone or array of microphones, may be included in the vehicle sensor subsystem 344. The microphones of the sound detection array may be configured to receive audio indications of the presence of, or instructions from, authorities, including sirens and commands such as “Pull over.” These microphones are mounted, or located, on the external portion of the vehicle, specifically on the outside of the tractor portion of an autonomous vehicle. Microphones used may be any suitable type, mounted such that they are effective both when the autonomous vehicle is at rest, as well as when it is moving at normal driving speeds.

The vehicle control subsystem 348 may be configured to control the operation of the autonomous vehicle 302 and its components. Accordingly, the vehicle control subsystem 348 may include various elements such as a throttle and gear selector 348a, a brake unit 348b, a navigation unit 348c, a steering system 348d, and/or an autonomous control unit 348e. The throttle and gear selector 348a may be configured to control, for instance, the operating speed of the engine and, in turn, control the speed of the autonomous vehicle 302. The throttle and gear selector 348a may be configured to control the gear selection of the transmission. The brake unit 348b can include any combination of mechanisms configured to decelerate the autonomous vehicle 302. The brake unit 348b can slow the autonomous vehicle 302 in a standard manner, including by using friction to slow the wheels or engine braking. The brake unit 348b may include an anti-lock brake system (ABS) that can prevent the brakes from locking up when the brakes are applied. The navigation unit 348c may be any system configured to determine a driving path or route for the autonomous vehicle 302. The navigation unit 348c may additionally be configured to update the driving path dynamically while the autonomous vehicle 302 is in operation. In some embodiments, the navigation unit 348c may be configured to incorporate data from the GPS transceiver 346g and one or more predetermined maps so as to determine the driving path for the autonomous vehicle 302. The steering system 348d may represent any combination of mechanisms that may be operable to adjust the heading of autonomous vehicle 302 in an autonomous mode or in a driver-controlled mode.

The autonomous control unit 348e may represent a control system configured to identify, evaluate, and avoid or otherwise negotiate potential obstacles or obstructions in the environment of the autonomous vehicle 302. In general, the autonomous control unit 348c may be configured to control the autonomous vehicle 302 for operation without a driver or to provide driver assistance in controlling the autonomous vehicle 302. In some embodiments, the autonomous control unit 348c may be configured to incorporate data from the GPS transceiver 346g, the radar unit 346b, the LiDAR unit 346f, the cameras 346a, and/or other vehicle subsystems to determine the driving path or trajectory for the autonomous vehicle 302.

The network communication subsystem 392 may comprise network interfaces, such as routers, switches, modems, and/or the like. The network communication subsystem 392 may be configured to establish communication between the autonomous vehicle 302 and other systems, servers, etc. The network communication subsystem 392 may be further configured to send and receive data from and to other systems.

Many or all of the functions of the autonomous vehicle 302 can be controlled by the in-vehicle control computer 350. The in-vehicle control computer 350 may include at least one data processor 370 (which can include at least one microprocessor) that executes processing instructions 380 stored in a non-transitory computer-readable medium, such as the data storage device 390 or memory. The in-vehicle control computer 350 may also represent a plurality of computing devices that may serve to control individual components or subsystems of the autonomous vehicle 302 in a distributed fashion. In some embodiments, the data storage device 390 may contain processing instructions 380 (e.g., program logic) executable by the data processor 370 to perform various methods and/or functions of the autonomous vehicle 302, including those described with respect to FIGS. 1-10.

The data storage device 390 may contain additional instructions as well, including instructions to transmit data to, receive data from, interact with, or control one or more of the vehicle drive subsystem 342, the vehicle sensor subsystem 344, and the vehicle control subsystem 348. The in-vehicle control computer 350 can be configured to include a data processor 370 and a data storage device 390. The in-vehicle control computer 350 may control the function of the autonomous vehicle 302 based on inputs received from various vehicle subsystems (e.g., the vehicle drive subsystem 342, the vehicle sensor subsystem 344, and the vehicle control subsystem 348).

FIG. 4 shows an exemplary system 400 for providing precise autonomous driving operations. The system 400 may include several modules that can operate in the in-vehicle control computer 350, as described in FIG. 3. The in-vehicle control computer 350 may include a sensor fusion module 402 shown in the top left corner of FIG. 4, where the sensor fusion module 402 may perform at least four image or signal processing operations. The sensor fusion module 402 can obtain images from cameras located on an autonomous vehicle to perform image segmentation 404 to detect the presence of moving objects (e.g., other vehicles, pedestrians, etc.,) and/or static obstacles (e.g., stop sign, speed bump, terrain, etc.,) located around the autonomous vehicle. The sensor fusion module 402 can obtain LiDAR point cloud data item from LiDAR sensors located on the autonomous vehicle to perform LiDAR segmentation 406 to detect the presence of objects and/or obstacles located around the autonomous vehicle.

The sensor fusion module 402 can perform instance segmentation 408 on image and/or point cloud data items to identify an outline (e.g., boxes) around the objects and/or obstacles located around the autonomous vehicle. The sensor fusion module 402 can perform temporal fusion 410 where objects and/or obstacles from one image and/or one frame of point cloud data item are correlated with or associated with objects and/or obstacles from one or more images or frames subsequently received in time.

The sensor fusion module 402 can fuse the objects and/or obstacles from the images obtained from the camera and/or point cloud data item obtained from the LiDAR sensors. For example, the sensor fusion module 402 may determine based on a location of two cameras that an image from one of the cameras comprising one half of a vehicle located in front of the autonomous vehicle is the same as the vehicle captured by another camera. The sensor fusion module 402 may send the fused object information to the tracking or prediction module 446 and the fused obstacle information to the occupancy grid module 460. The in-vehicle control computer may include the occupancy grid module 460 which can retrieve landmarks from a map database 458 stored in the in-vehicle control computer. The occupancy grid module 460 can determine drivable areas and/or obstacles from the fused obstacles obtained from the sensor fusion module 402 and the landmarks stored in the map database 458. For example, the occupancy grid module 460 can determine that a drivable area may include a speed bump obstacle.

As shown in FIG. 4 below the sensor fusion module 402, the in-vehicle control computer (350 in FIG. 3) may include a LiDAR-based object detection module 412 that can perform object detection 416 based on point cloud data item obtained from the LiDAR sensors 414 located on the autonomous vehicle. The object detection 416 technique can provide a location (e.g., in 3D world coordinates) of objects from the point cloud data item. Below the LiDAR-based object detection module 412, the in-vehicle control computer may include an image-based object detection module 418 that can perform object detection 424 based on images obtained from cameras 420 located on the autonomous vehicle. For example, the object detection 418 technique can employ a deep image-based object detection 424 (e.g., a machine learning technique) to provide a location (e.g., in 3D world coordinates) of objects from the image provided by the camera 420.

The radar 456 on the autonomous vehicle can scan an area surrounding the autonomous vehicle or an area towards which the autonomous vehicle is driven. The Radar data may be sent to the sensor fusion module 402 that can use the Radar data to correlate the objects and/or obstacles detected by the radar 456 with the objects and/or obstacles detected from both the LiDAR point cloud data item and the camera image. The Radar data also may be sent to the tracking or prediction module 446 that can perform data processing on the Radar data to track objects by object tracking module 448 as further described below.

The in-vehicle control computer may include a tracking or prediction module 446 that receives the locations of the objects from the point cloud and the objects from the image, and the fused objects from the sensor fusion module 402. The tracking or prediction module 446 also receives the Radar data with which the tracking or prediction module 446 can track objects by object tracking module 448 from one point cloud data item and one image obtained at one time instance to another (or the next) point cloud data item and another image obtained at another subsequent time instance.

The tracking or prediction module 446 may perform object attribute estimation 450 to estimate one or more attributes of an object detected in an image or point cloud data item. The one or more attributes of the object may include a type of object (e.g., pedestrian, car, or truck, etc.). The tracking or prediction module 446 may perform behavior prediction 452 to estimate or predict the motion pattern of an object detected in an image and/or a point cloud. The behavior prediction 452 can be performed to detect a location of an object in a set of images received at different points in time (e.g., sequential images) or in a set of point cloud data items received at different points in time (e.g., sequential point cloud data items). In some embodiments, the behavior prediction 452 can be performed for each image received from a camera and/or each point cloud data item received from the LiDAR sensor. In some embodiments, the tracking or prediction module 446 can be performed (e.g., run or executed) on received data to reduce computational load by performing behavior prediction 452 on every other or after every pre-determined number of images received from a camera or point cloud data item received from the LiDAR sensor (e.g., after every two images or after every three-point cloud data items).

The behavior prediction 452 feature may determine the speed and direction of the objects that surround the autonomous vehicle from the Radar data, where the speed and direction information can be used to predict or determine motion patterns of objects. A motion pattern may comprise a predicted trajectory information of an object over a pre-determined length of time in the future after an image is received from a camera. Based on the motion pattern predicted, the tracking or prediction module 446 may assign motion pattern situational tags to the objects (e.g., “located at coordinates (x,y),” “stopped,” “driving at 50 mph,” “speeding up” or “slowing down”). The situation tags can describe the motion pattern of the object. The tracking or prediction module 446 may send the one or more object attributes (e.g., types of the objects) and motion pattern situational tags to the planning module 462. The tracking or prediction module 446 may perform an environment analysis 454 using any information acquired by system 400 and any number and combination of its components.

The in-vehicle control computer may include the planning module 462 that receives the object attributes and motion pattern situational tags from the tracking or prediction module 446, the drivable area and/or obstacles, and the vehicle location and pose information from the fused localization module 426 (further described below).

The planning module 462 can perform navigation planning 464 to determine a set of trajectories on which the autonomous vehicle can be driven. The set of trajectories can be determined based on the drivable area information, the one or more object attributes of objects, the motion pattern situational tags of the objects, location of the obstacles, and the drivable area information. In some embodiments, the navigation planning 464 may include determining an area next to the road where the autonomous vehicle can be safely parked in a case of emergencies. The planning module 462 may include behavioral decision making 466 to determine driving actions (e.g., steering, braking, throttle) in response to determining changing conditions on the road (e.g., traffic light turned yellow, or the autonomous vehicle is in an unsafe driving condition because another vehicle drove in front of the autonomous vehicle and in a region within a pre-determined safe distance of the location of the autonomous vehicle). The planning module 462 performs trajectory generation 468 and selects a trajectory from the set of trajectories determined by the navigation planning operation 464. The selected trajectory information may be sent by the planning module 462 to the control module 470.

The in-vehicle control computer may include a control module 470 that receives the proposed trajectory from the planning module 462 and the autonomous vehicle location and pose from the fused localization module 426. The control module 470 may include a system identifier 472. The control module 470 can perform a model-based trajectory refinement 474 to refine the proposed trajectory. For example, the control module 470 can apply filtering (e.g., Kalman filter) to make the proposed trajectory data smooth and/or to minimize noise. The control module 470 may perform the robust control 476 by determining, based on the refined proposed trajectory information and current location and/or pose of the autonomous vehicle, an amount of brake pressure to apply, a steering angle, a throttle amount to control the speed of the vehicle, and/or a transmission gear. The control module 470 can send the determined brake pressure, steering angle, throttle amount, and/or transmission gear to one or more devices in the autonomous vehicle to control and facilitate precise driving operations of the autonomous vehicle.

The deep image-based object detection 424 performed by the image-based object detection module 418 can also be used detect landmarks (e.g., stop signs, speed bumps, etc.,) on the road. The in-vehicle control computer may include a fused localization module 426 that obtains landmarks detected from images, the landmarks obtained from a map database 436 stored on the in-vehicle control computer, the landmarks detected from the point cloud data item by the LiDAR-based object detection module 412, the speed and displacement from the odometer sensor 444, or a rotary encoder, and the estimated location of the autonomous vehicle from the GPS/IMU sensor 438 (e.g., GPS sensor 440 and IMU sensor 442) located on or in the autonomous vehicle. Based on this information, the fused localization module 426 can perform a localization operation 428 to determine a location of the autonomous vehicle, which can be sent to the planning module 462 and the control module 470.

The fused localization module 426 can estimate pose 430 of the autonomous vehicle based on the GPS and/or IMU sensors 438. The pose of the autonomous vehicle can be sent to the planning module 462 and the control module 470. The fused localization module 426 can also estimate status (e.g., location, possible angle of movement) of the trailer unit based on (e.g., trailer status estimation 434), for example, the information provided by the IMU sensor 442 (e.g., angular rate and/or linear velocity). The fused localization module 426 may also check the map content 432.

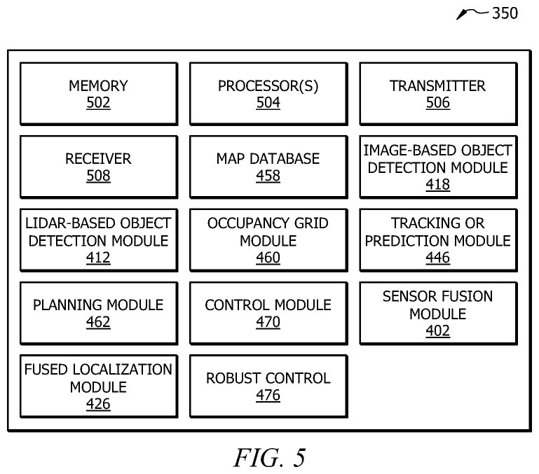

FIG. 5 shows an exemplary block diagram of an in-vehicle control computer 350 included in an autonomous vehicle 302. The in-vehicle control computer 350 may include at least one processor 504 and a memory 502 having instructions stored thereupon (e.g., software instructions 138 and processing instructions 380 in FIGS. 1 and 3, respectively). The instructions, upon execution by the processor 504, configure the in-vehicle control computer 350 and/or the various modules of the in-vehicle control computer 350 to perform the operations described in FIGS. 1-6. The transmitter 506 may transmit or send information or data to one or more devices in the autonomous vehicle. For example, the transmitter 506 can send an instruction to one or more motors of the steering wheel to steer the autonomous vehicle. The receiver 508 receives information or data transmitted or sent by one or more devices. For example, the receiver 508 receives a status of the current speed from the odometer sensor or the current transmission gear from the transmission. The transmitter 506 and receiver 508 also may be configured to communicate with the plurality of vehicle subsystems 340 and the in-vehicle control computer 350 described above in FIGS. 3 and 4.

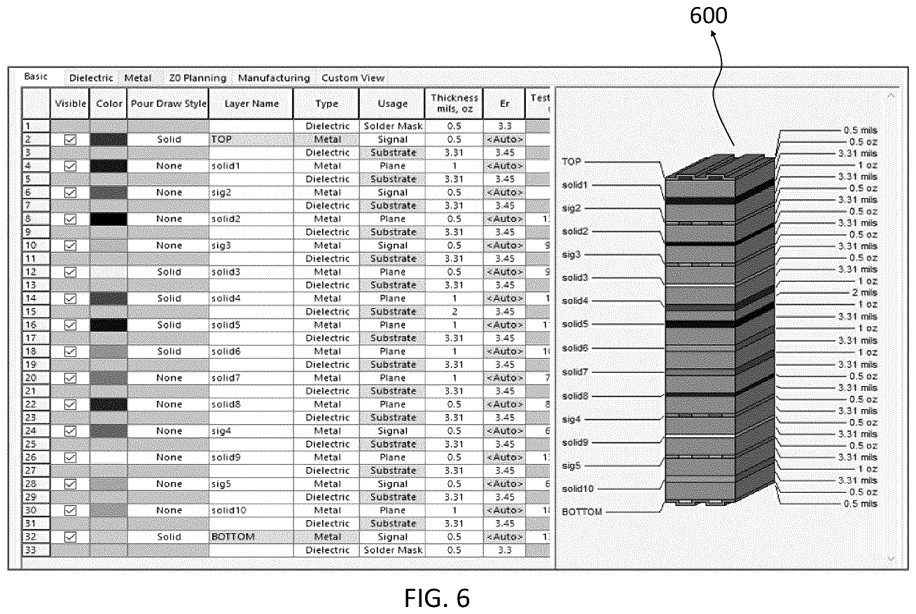

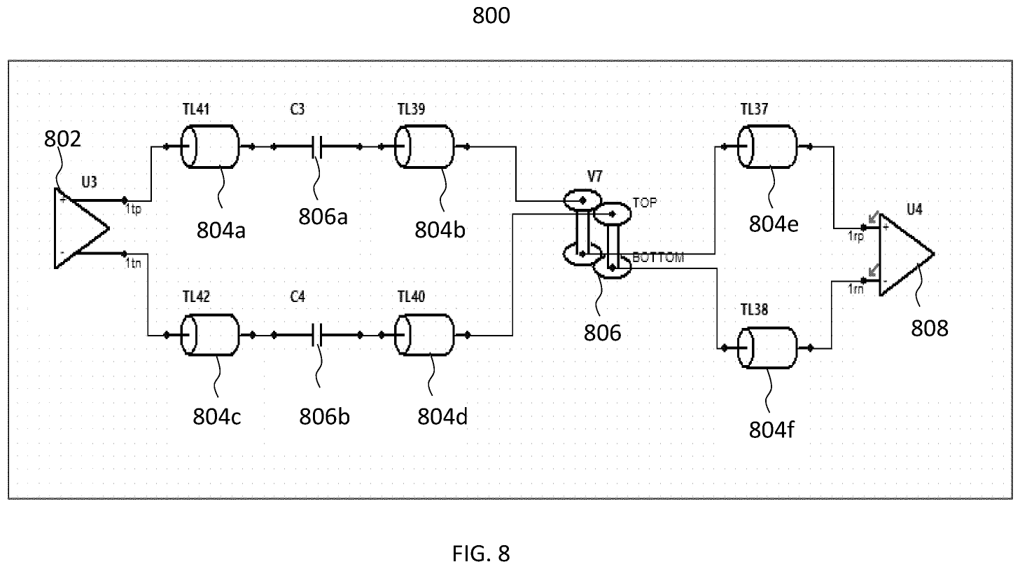

FIG. 6 illustrates an example configuration for a stack of layers 600 in circuit boards used in connecting one component (104 in FIG. 1) of the enclosure (102 in FIG. 1) to another component (104 in FIG. 1) of the enclosure. As shown in FIG. 6, the stack of layers 600 includes 16 layers. In other examples, the stack of layers 600 may include any suitable number of layers. The transmission lines on the circuit boards may be placed on any combination of layers in the stack of layers 600. If a transmission line is routed from one layer to another, a via may be used to establish routing a transmission line from one layer to another. An example configuration of a via is described in FIG. 8. The location and dimension of a transmission line may affect the electrical signal being transmitted by the transmission line and the signal integrity of the electrical signal. The transmission lines are designed to be placed on certain layers and with certain dimensions and locations to support the requirements (148 in FIG. 1) of the enclosure (102 in FIG. 1).

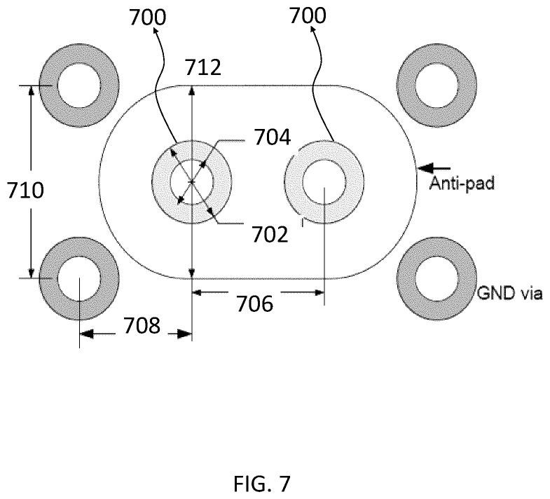

FIG. 7 illustrates an embodiment of a via 700 for use in a circuit board that connects one component (104 in FIG. 1) of the enclosure (102 in FIG. 1) from one layer to another component (104 in FIG. 1) of the enclosure in another layer of the circuit board. The via 700 may form an electrical connection between copper layers of a printer circuit board (PCB). Essentially, a via 700 is a drilled hole that goes through two or more adjacent layers of the circuit board. The hole is plated with copper that forms an electrical connection through the insulation that separates the copper layers of the circuit board. The dimension of the via 700 may affect the electrical connection and the signal integrity that travels through the via 700. The dimension of the via 700 may be determined to increase the power ad signal integrity of the transmitted signal through the via 700.

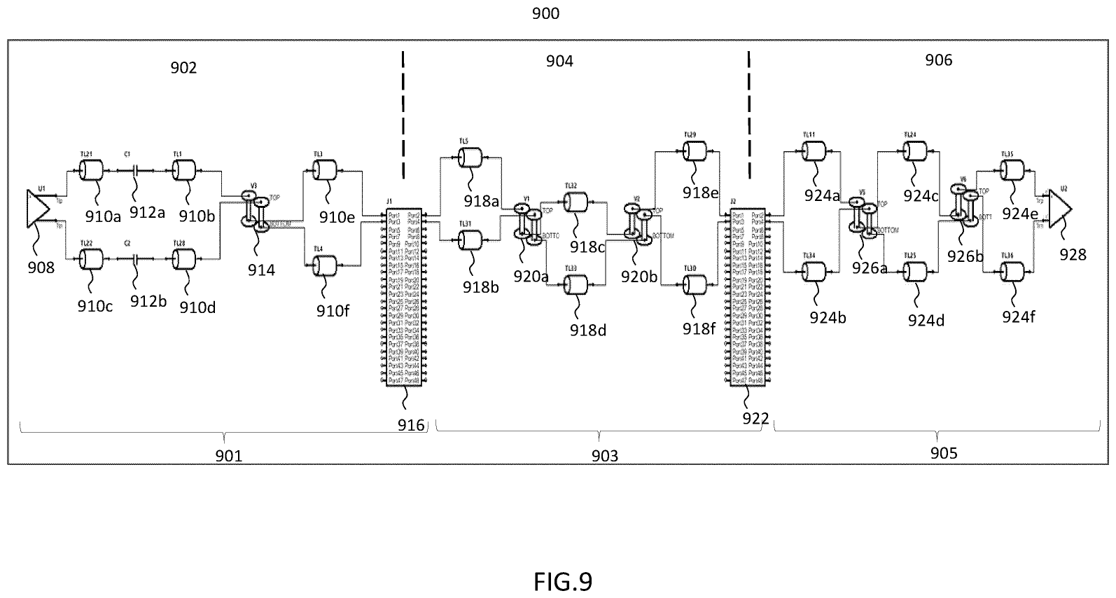

In the example of FIG. 7, each via 700 has an outer radius of 702 and an inner radius 704. The inner and outer radios 704, 702 may be designed to provide an electrical signal transmission with the desired power, amplitude, and frequency, integrity among other characteristics. The pair of vias 700 is used to transmit the differential electrical signals from one layer of the circuit board to another layer. In the illustrated example, the distance between the vias 700 is distance 706. The distance 706 may be determined (through simulations) to reduce interference noises on the differential electrical signals. Further to reduce interference noises and other noises, ground (GND) vias may be used in conjunction with the vias 700, similar to that shown in FIG. 7. The distance between a via 700 and a GND via is distance 708. The distance between the GND vias is distance 710. The anti-pad area may form a barrier or boundary around the vias 700. The height of the anti-pad is height 712. The distances 706, 708, 710, and height 712 are determined (through simulation) to achieve a configuration that helps to satisfy the requirements (148 in FIG. 1). The vias 700 may be modeled on a schematic diagram similar to that described in FIGS. 8 and 9.

FIG. 8 illustrates an example schematic diagram of a circuit 800 for modeling a communication path between two components (104 in FIG. 1) or between two blades (118 in FIG. 1). The circuit 800 may be used for modeling physical properties of various components along a path of electrical signals between two components (104 in FIG. 1) or between two blades (118 in FIG. 1). As seen in FIG. 8, the example schematic diagram of the circuit 800 includes a peripheral component interconnect express (PCIe) interfaces 802, 808, transmission lines 804a-f, capacitors 806a-b, and a via 806. The PCIe interface 802 may be associated with a first component of the enclosure (104 in FIG. 1). The PCIe interface 802 may be configured to transmit electrical signals to the second component of the enclosure (104 in FIG. 1). The differential electrical signals may be transmitted from the two outputs ports of the PCIe interface 802 and travel through the paths to reach the respective input ports of the PCIe interface 808.

The transmission lines 804a-f are generally used for modeling physical traces on the circuit board that form the circuit 800. The transmission lines 804a-f may be configured to emulate the physical properties of the physical traces. For example, the physical traces may be electrical signals conducting copper lines that are manufactured on the circuit board 800. The transmission lines are generally copper lines or trances that are designed to conduct electromagnetic signals. A transmission line may be formed over a dielectric material that forms the circuit board. The capacitors 806a-b generally represent or model parasitic capacitance along the transmission lines. The via 806 may be an instance of a via discussed with respect to FIG. 7. The via 806 may be used to transmit the electrical signal received from the PCIe interface 802 (on one layer of the circuit board 800) to another layer of the circuit board 800. The modeling of the communication path from one component of the enclosure (104 in FIG. 1) to another component may aid to determine an arrangement of components so that the requirements (148 in FIG. 1) are satisfied.

FIG. 9 illustrates an example schematic diagram of a circuit 900 for modeling a communication path from a first component 902 to a second component 904 to a third component 906. In some examples, the component 902 may be a component 104 of the enclosure described in FIG. 1, the component 904 may be backplane 204 described in FIG. 2, and the component 906 may be a component 104 of the enclosure described in FIG. 1. In some examples, each of the components 902, 904, and 906 may be a component 104 of the enclosure described in FIG. 1. In the illustrated example of FIG. 9, the circuit 900 may include a first section 901, a second section 903, and a third section 905. The first section 901 of the circuit 900 may correspond to modeling a communication path from the first component 902 to the second component 904. The second section 903 of the circuit 900 may correspond to modeling a communication path from the second component 904 to the third component 906. The third section 905 of the circuit 900 may correspond to modeling a communication path at the third component 906.

The first section 901 of the circuit 900 may include a PCIe interface 908, transmission lines 912a-f, capacitors 912a-b, and a via 914. The PCIe interface 908 may be used as a driver to create electrical signals. The electrical signals may flow through the output ports of the PCIe interface 908 toward the transmission lines 910a and 910c, respectively. Ultimately, the electrical signals may flow through the communication paths from the first component 902 to the second component 904 and to the third component 906 and reach the PCIe interface 928.

The transmission lines 910a-f are generally used for modeling physical traces on the circuit board at the first section 901 of the circuit 900. The transmission lines 910a-f may be configured to emulate the physical properties of the physical traces. For example, the physical traces may be electrically conducting copper lines that are manufactured on the circuit board 900. The transmission lines are generally copper lines or trances that are designed to conduct electromagnetic signals. A transmission line may be formed over a dielectric material that forms the circuit board. The capacitors 912a-b generally represent parasitic capacitance along the transmission lines.

The via 914 generally represents an electrical connection between copper layers in a printed circuit board (PCB) that forms the circuit 900. The via 914 may be configured to emulate an electrical connection between a component on one layer of the circuit board to another component on another layer of the circuit board. The via 914 may be an instance of a via discussed with respect to FIG. 7.

The s-parameter component 916 may be configured to model the connectors that are used to connect the first component 902 to the second component 904. The first component 902 may be connected to the second component 904 via the s-parameter component 916.

The second section 903 of the circuit board 900 may include transmission lines 918a-f and vias 920a-b. The transmission lines 918a-f may represent physical traces on the circuit board at the second section 903. In one example, transmission lines 918a-f may be substantially similar to other transmission lines 910a-f. For example, transmission lines 918a-f may substantially have the same or similar physical properties (such as resistance, length, width, material, etc.) as transmission line 918a-f. In other examples, transmission lines 918a-f may have different physical properties compared to other transmission lines 910a-f. The vias 920a-b may be configured to emulate an electrical connection between a component on one layer of the circuit board to another component on another layer of the circuit board. The vias 920a-b may be an instance of a via discussed with respect to FIG. 7. In some examples, the vias 920a-b may be substantially the same or similar as the via 914. In other examples, the vias 920a-b may be different from the via 914—such that the vias 920a-b may be connecting different layers on the circuit board compared to the via 914. The s-parameter component 922 may be configured to model the connectors that are used to connect the second component 904 to the third component 906. The third component 906 may be connected to the second component 904 via the s-parameter component 922.

The third section 905 of the circuit 900 may include transmission lines 924a-f, vias 926a-b, and a PCIe interface 928. The transmission lines 924a-f may represent physical traces on the circuit board at the third section 905. In one example, transmission lines 924a-f may be substantially similar to other transmission lines on the circuit board 900. For example, the transmission lines 924a-f may substantially have the same or similar physical properties (such as resistance, length, width, material, etc.) as other transmission lines. In other examples, the transmission lines 924a-f may have different physical properties compared to other transmission lines on the circuit board 900.

The vias 926a-b may be configured to emulate an electrical connection between a component on one layer of the circuit board to another component on another layer of the circuit board. The vias 926a-b may be instances of a via discussed with respect to FIG. 7.

The PCIe interface 928 may be configured to emulate a receiver that receives the electrical signals from the PCIe interface 908, where the electrical signals travel through the communication paths from the PCIe interface 908 toward the PCIe interface 928. The differential electrical signals from two outputs of the PCIe interface 908 may travel through the transmission lines 910a-f, 918a-f, and 924a-f, capacitors 912a-b, vias 914, 920a-b, and 926a-b, and s-parameter components 916, 922 to reach the PCIe interface 928.

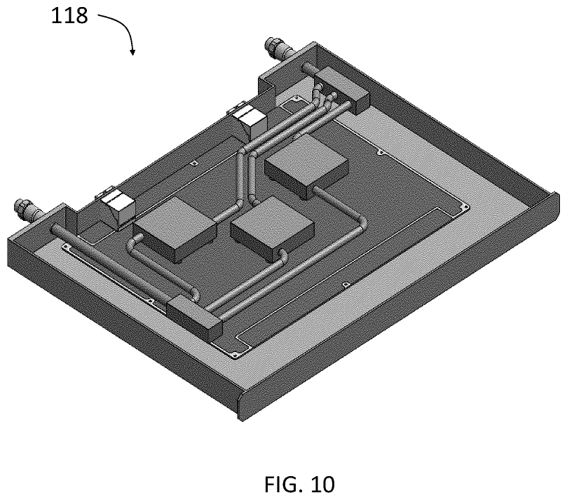

FIG. 10 illustrates an isometric view of an example embodiment of a blade 118. In the illustrated embodiment of the blade 118, the pinout sizes and the connectors on blade 118 are determined through simulations of circuit boards described in FIGS. 8 and 9 to determine how to arrange various components of the blade 118 in a manner that the enclosure satisfies the requirements (148 in FIG. 1). In other words, the pinout sizes and the connectors on the blade 118 are designed to reduce the form-factor to a desired form-factor while the signal integrity of the transmitted signals and cooling requirements are met.

While several embodiments have been provided in this disclosure, it should be understood that the disclosed systems and methods might be embodied in many other specific forms without departing from the spirit or scope of this disclosure. The present examples are to be considered as illustrative and not restrictive, and the intention is not to be limited to the details given herein. For example, the various elements or components may be combined or integrated into another system or certain features may be omitted, or not implemented.

In addition, techniques, systems, subsystems, and methods described and illustrated in the various embodiments as discrete or separate may be combined or integrated with other systems, modules, techniques, or methods without departing from the scope of this disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

To aid the Patent Office, and any readers of any patent issued on this application in interpreting the claims appended hereto, applicants note that they do not intend any of the appended claims to invoke 35 U.S.C. § 112 (f) as it exists on the date of filing hereof unless the words “means for” or “step for” are explicitly used in the particular claim.

Implementations of the disclosure can be described in view of the following clauses, the features of which can be combined in any reasonable manner.

Clause 1. A system comprising:
an autonomous vehicle configured to travel on a road autonomously; and
an enclosure associated with the autonomous vehicle, and configured to:
   house a set of components that facilitates an autonomous function of the autonomous vehicle, wherein the set of components comprises:
      a sensor processing unit that is configured to detect objects from sensor data captured by at least one sensor;
      a compute unit that is configured to determine a navigation path for the autonomous vehicle based at least in part upon an input signal received from the sensor processing unit;
      a vehicle control unit that is configured to control the autonomous function of the autonomous vehicle based at least in part upon input signals received from other components from among the set of components;
      a communication gateway that is configured to establish communications between the autonomous vehicle and other devices; and
      a data diagnostics unit that is configured to determine a health data for at least one component of the autonomous vehicle;
   meet a set of requirements comprising a space requirement, a communication requirement, a cooling requirement, and a shock absorption requirement, wherein:
      the space requirement indicates that the enclosure to have a dimension less than a threshold dimension;
      the communication requirement indicates to provide transmission lines to facilitate a communication throughput more than a threshold communication throughput among the set of components;
      the cooling requirement indicates to satisfy a threshold temperature within the enclosure; and
      the shock absorption requirement indicates to satisfy a threshold damping factor;
wherein:
   the enclosure comprises a backplane that is configured to satisfy the communication requirement;
   the backplane comprises the transmission lines that enable communications among the components of the set of components;
   the backplane is connected to a set of manifolds configured to provide a flow of coolant between a heat exchanger and each of the set of components;
   the backplane further comprises a set of connectors to connect at least one of the set of components to the at least one sensor;
   the backplane is positioned across a side of the set of components and against a back wall of the enclosure.

Clause 2. The system of Clause 1, wherein the enclosure is modular such that the enclosure is configured to be integrated with a semi-tractor truck.

Clause 3. The system of Clause 1, wherein the communication requirement further indicates to provide the communication throughput between at least one component of the set of components and the other devices.

Clause 4. The system of Clause 1, wherein the other devices comprise at least one of:
an oversight server configured to provide software resources to the autonomous vehicle; or
one or more other autonomous vehicles.

Clause 5. The system of Clause 1, wherein the threshold dimension is 36 inches×24 inches×22 inches.

Clause 6. The system of Clause 1, wherein the enclosure is placed within a cabin of the autonomous vehicle.

Clause 7. The system of Clause 1, wherein the enclosure is placed between a driver seat and a passenger seat of the autonomous vehicle.

Clause 8. The system of Clause 1, wherein the cooling requirement is satisfied by a liquid-based cooling system.

Clause 9. The system of Clause 1, wherein the communication requirement further indicates to facilitate the communication throughput more than the threshold communication throughput between at least one component of the set of components and the other devices.

Clause 10. The system of Clause 1, wherein the enclosure further comprises a cooling system configured to satisfy the cooling requirement.

Clause 11. A physical enclosure, comprising:
a set of components that facilitates an autonomous function of an autonomous vehicle, wherein the set of components comprises:
   a sensor processing unit that is configured to detect objects from sensor data captured by at least one sensor;
   a compute unit that is configured to determine a navigation path for the autonomous vehicle based at least in part upon an input signal received from the sensor processing unit;
   a vehicle control unit that is configured to control the autonomous function of the autonomous vehicle based at least in part upon input signals received from other components from among the set of components;
   a communication gateway that is configured to establish communications between the autonomous vehicle and other devices; and
   a data diagnostics unit that is configured to determine a health data for at least one component of the autonomous vehicle;
wherein the physical enclosure is configured to:
house the set of components; and
meet a set of requirements comprising a space requirement, a communication requirement, a cooling requirement, and a shock absorption requirement, wherein:
   the space requirement indicates that the physical enclosure to have a dimension less than a threshold dimension;
   the communication requirement indicates to provide transmission lines to facilitate a communication throughput more than a threshold communication throughput among the set of components;
   the cooling requirement indicates to satisfy a threshold temperature within the physical enclosure; and
   the shock absorption requirement indicates to satisfy a threshold damping factor;
wherein:
the physical enclosure comprises a backplane that is configured to satisfy the communication requirement;
the backplane comprises the transmission lines that enable communications among the components of the set of components;
the backplane connected to a set of manifolds configured to flow a cooled liquid toward the set of components;
the backplane further comprises a set of connectors to connect at least one of the set of components to the at least one sensor;
the backplane is positioned across a side of the set of components and against a back wall of the physical enclosure.

Clause 12. The physical enclosure of Clause 11, wherein a cooling system comprises:
the set of manifolds configured to flow a cooled liquid toward the set of components; and
a dual pump configured to pump the cooled liquid to the set of components.

Clause 13. The physical enclosure of Clause 11, wherein:
the physical enclosure further comprises a shock absorption system configured to satisfy the shock absorption requirement;
the shock absorption system comprises a plurality of shock dampeners positioned at various locations underneath the physical enclosure; and
each of the plurality of shock dampeners is configured to dampen vibrations caused by movements of the autonomous vehicle while traveling.

Clause 14. The physical enclosure of Clause 11, wherein:
each component of the set of components is implemented by a circuit board on a blade;
the blade is a computing device with a predefined dimension that fits into a bay within the physical enclosure;
the circuit board comprises a set of electrical components that is configured to perform an operation of a component of the set of components; and
the set of electrical components comprises at least one hardware processor.

Clause 15. The physical enclosure of Clause 14, wherein:
the blade comprises a set of connectors configured to accept one or more manifolds of a cooling system and a set of transmission lines associated with the backplane; and
the blade is configured to be connected to the one or more manifolds and the set of transmission lines via the set of connectors when the blade is slid into the bay within the physical enclosure.

Clause 16. The physical enclosure of Clause 11, wherein the autonomous vehicle is a semi-truck tractor unit attached to a trailer.

Clause 17. The physical enclosure of Clause 11, wherein the at least one sensor comprises a camera, a light detection and ranging sensor, a motion sensor, a Radar sensor, or an infrared sensor.

Clause 18. The physical enclosure of Clause 11, wherein the physical enclosure is modular such that the physical enclosure is configured to be integrated with a semi-tractor truck.

Clause 19. The physical enclosure of Clause 11, wherein the communication requirement further indicates to provide the communication throughput between at least one component of the set of components and the other devices.

Clause 20. The physical enclosure of Clause 11, wherein the other devices comprise at least one of:
an oversight server configured to provide software resources to the autonomous vehicle; or
one or more other autonomous vehicles.

1. A system, comprising:
an autonomous vehicle configured to travel on a road autonomously; and
an enclosure associated with the autonomous vehicle, and configured to:
house a set of components that facilitates an autonomous function of the autonomous vehicle, wherein the set of components comprises:
a sensor processing unit that is configured to detect objects from sensor data captured by at least one sensor;
a compute unit that is configured to determine a navigation path for the autonomous vehicle based at least in part upon an input signal received from the sensor processing unit;
a vehicle control unit that is configured to control the autonomous function of the autonomous vehicle based at least in part upon input signals received from other components from among the set of components;
a communication gateway that is configured to establish communications between the autonomous vehicle and other devices; and
a data diagnostics unit that is configured to determine a health data for at least one component of the autonomous vehicle;
meet a set of requirements comprising a space requirement, a communication requirement, a cooling requirement, and a shock absorption requirement, wherein:
the space requirement indicates that the enclosure to have a dimension less than a threshold dimension;
the communication requirement indicates to provide transmission lines to facilitate a communication throughput more than a threshold communication throughput among the set of components;
the cooling requirement indicates to satisfy a threshold temperature within the enclosure; and
the shock absorption requirement indicates to satisfy a threshold damping factor;
wherein:
the enclosure comprises a backplane that is configured to satisfy the communication requirement;
the backplane comprises the transmission lines that enable communications among the components of the set of components;
the backplane is connected to a set of manifolds configured to provide a flow of coolant between a heat exchanger and each of the set of components;
the backplane further comprises a set of connectors to connect at least one of the set of components to the at least one sensor;
the backplane is positioned across a side of the set of components and against a back wall of the enclosure.

2. The system of claim 1, wherein the enclosure is modular such that the enclosure is configured to be integrated with a semi-tractor truck.

3. The system of claim 1, wherein the communication requirement further indicates to provide the communication throughput between at least one component of the set of components and the other devices.

4. The system of claim 1, wherein the other devices comprise at least one of:
an oversight server configured to provide software resources to the autonomous vehicle; or
one or more other autonomous vehicles.

5. The system of claim 1, wherein the threshold dimension is 36 inches×24 inches×22 inches.

6. The system of claim 1, wherein the enclosure is placed within a cabin of the autonomous vehicle.

7. The system of claim 1, wherein the enclosure is placed between a driver seat and a passenger seat of the autonomous vehicle.

8. The system of claim 1, wherein the cooling requirement is satisfied by a liquid-based cooling system.

9. The system of claim 1, wherein the communication requirement further indicates to facilitate the communication throughput more than the threshold communication throughput between at least one component of the set of components and the other devices.

10. The system of claim 1, wherein the enclosure further comprises a cooling system configured to satisfy the cooling requirement.

11. A physical enclosure, comprising:
a set of components that facilitates an autonomous function of an autonomous vehicle, wherein the set of components comprises:
a sensor processing unit that is configured to detect objects from sensor data captured by at least one sensor;
a compute unit that is configured to determine a navigation path for the autonomous vehicle based at least in part upon an input signal received from the sensor processing unit;
a vehicle control unit that is configured to control the autonomous function of the autonomous vehicle based at least in part upon input signals received from other components from among the set of components;
a communication gateway that is configured to establish communications between the autonomous vehicle and other devices; and
a data diagnostics unit that is configured to determine a health data for at least one component of the autonomous vehicle;
wherein the physical enclosure is configured to:
house the set of components; and
meet a set of requirements comprising a space requirement, a communication requirement, a cooling requirement, and a shock absorption requirement, wherein:
the space requirement indicates that the physical enclosure to have a dimension less than a threshold dimension;
the communication requirement indicates to provide transmission lines to facilitate a communication throughput more than a threshold communication throughput among the set of components;
the cooling requirement indicates to satisfy a threshold temperature within the physical enclosure; and
the shock absorption requirement indicates to satisfy a threshold damping factor;
wherein:
the physical enclosure comprises a backplane that is configured to satisfy the communication requirement;
the backplane comprises the transmission lines that enable communications among the components of the set of components;
the backplane connected to a set of manifolds configured to flow a cooled liquid toward the set of components;
the backplane further comprises a set of connectors to connect at least one of the set of components to the at least one sensor;
the backplane is positioned across a side of the set of components and against a back wall of the physical enclosure.

12. The physical enclosure of claim 11, wherein a cooling system comprises:
the set of manifolds configured to flow a cooled liquid toward the set of components; and
a dual pump configured to pump the cooled liquid to the set of components.

13. The physical enclosure of claim 11, wherein:
the physical enclosure further comprises a shock absorption system configured to satisfy the shock absorption requirement;
the shock absorption system comprises a plurality of shock dampeners positioned at various locations underneath the physical enclosure; and
each of the plurality of shock dampeners is configured to dampen vibrations caused by movements of the autonomous vehicle while traveling.

14. The physical enclosure of claim 11, wherein:
each component of the set of components is implemented by a circuit board on a blade;
the blade is a computing device with a predefined dimension that fits into a bay within the physical enclosure;
the circuit board comprises a set of electrical components that is configured to perform an operation of a component of the set of components; and
the set of electrical components comprises at least one hardware processor.

15. The physical enclosure of claim 14, wherein:
the blade comprises a set of connectors configured to accept one or more manifolds of a cooling system and a set of transmission lines associated with the backplane; and
the blade is configured to be connected to the one or more manifolds and the set of transmission lines via the set of connectors when the blade is slid into the bay within the physical enclosure.

16. The physical enclosure of claim 11, wherein the autonomous vehicle is a semi-truck tractor unit attached to a trailer.

17. The physical enclosure of claim 11, wherein the at least one sensor comprises a camera, a light detection and ranging sensor, a motion sensor, a Radar sensor, or an infrared sensor.

18. The physical enclosure of claim 11, wherein the physical enclosure is modular such that the physical enclosure is configured to be integrated with a semi-tractor truck.

19. The physical enclosure of claim 11, wherein the communication requirement further indicates to provide the communication throughput between at least one component of the set of components and the other devices.

20. The physical enclosure of claim 11, wherein the other devices comprise at least one of:
an oversight server configured to provide software resources to the autonomous vehicle; or
one or more other autonomous vehicles.
